(19) United States
(12) Patent Application Publication
(10) Pub. No.: US 2008/0273305 A1
(43) Pub. Date: Nov. 6, 2008

(54) Fan airflow-guiding device

(76) Inventor: Jia-Shiung Lee, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/797,105

(22) Filed: May 1, 2007

(51) Int. Cl. H05K 7/20

(52) U.S. Cl. 361/695

(57) ABSTRACT

A fan airflow-guiding device matches a cooling fan. One side of the cooling fan has an outlet. The fan airflow-guiding device includes a frame and a plurality of airflow-guiding boards. The frame is assembled on one side of the cooling fan. The airflow-guiding boards are disposed on an outlet of the cooling fan in a predetermined direction and in parallel. The airflow-guiding boards are pivoted in the frame, and its slanting angle is adjustable. Thereby, by adjusting the slanting angle of the airflow-guiding boards, the airflow exhausted from the cooling fan is guided to a predetermined location and the airflow direction of the cooling fan is adjusted.

### BACKGROUND OF THE INVENTION

1. Field of the Invention

The present invention relates to a fan airflow-guiding device. In particular, this invention relates to a fan airflow-guiding device that matches a cooling fan and has a plurality of angle-adjustable airflow-guiding boards for guiding the direction of the airflow exhausted from the cooling fan.

2. Description of the Related Art

Reference id made to FIG. 1. The cooling fan of the prior art includes a housing 10a, and a fan leaf 20a. There is an outlet 11a on the front side of the housing 10a, and there is an inlet 12a on the rear side of the housing 10a. The fan leaf 20a is pivoted at the center of the housing 10a. When the fan leaf 20a is rotating, the cooling fan absorbs airflow from the inlet 12a, and exhausts airflow to the outlet 11 a to cool a heat source, such as a CPU, or a display chip, etc, (not shown in FIG. 1).

However, airflow generated from the cooling fan of the prior art can merely be exhausted along the axial direction of the outlet 11a to cool the target object located at the front section of the outlet 11a. If the heat source is not located at the front section of the outlet 11a, the cooling fan cannot directly blow onto the heat source so its cooling efficiency is poor. Furthermore, because the airflow direction of the cooling fan cannot be adjusted, the user cannot guide the airflow to a specified heat source.

### SUMMARY OF THE INVENTION

One particular aspect of the present invention is to provide a fan airflow-guiding device. The fan airflow-guiding device has a plurality of angle-adjustable airflow-guiding boards. The fan airflow-guiding device matches a cooling fan for guiding the airflow exhausted from the cooling fan to a specified direction.

Another particular aspect of the present invention is to provide a fan airflow-guiding device. The fan airflow-guiding device matches a cooling fan and a housing for absorbing cool air into the housing from outside of the housing, and guiding cool air to a target object that is to be cooled.

The fan airflow-guiding device matches a cooling fan. The fan airflow-guiding device includes a frame assembled on one side of the cooling fan, and a plurality of airflow-guiding boards pivoted in the frame. The airflow-guiding boards are disposed on an outlet of the cooling fan in a predetermined direction.

The present invention has the following characteristics. The fan airflow-guiding device of the present invention is attached onto the cooling fan. The original structure of the cooling fan does not need to be modified. According the user's needs, the airflow direction of the cooling fan can be adjusted. Therefore, the user can guide the airflow to a specified heat source for cooling the heat source more rapidly.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is a perspective view of the cooling fan of the prior art;

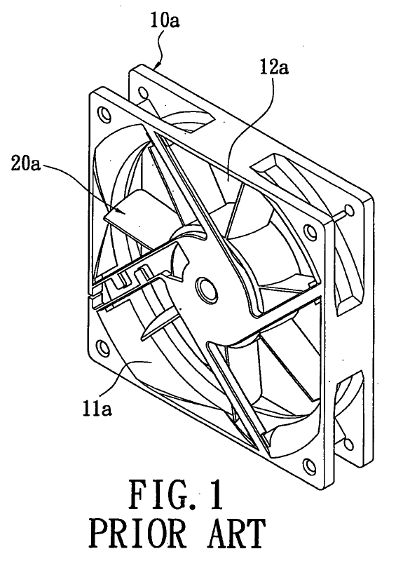

FIG. 2 is an exploded perspective view of the first embodiment of the present invention;

FIG. 3 is a schematic diagram of the first embodiment of the present invention;

FIG. 4 is another schematic diagram of the first embodiment of the present invention;

FIG. 5 is an exploded perspective view of the second embodiment of the present invention;

FIG. 6 is an amplified diagram of part A in FIG. 5;

FIG. 7 is an assembly perspective view of the second embodiment of the present invention;

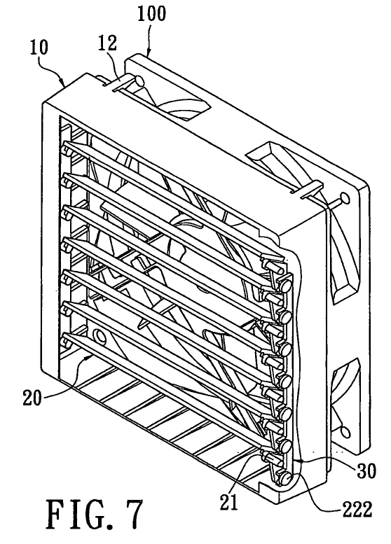

FIG. 8 is an assembly perspective view of the third embodiment of the present invention;

FIG. 9 is another assembly perspective view of the third embodiment of the present invention;

FIG. 10 is an assembly perspective view of the fourth embodiment of the present invention; and

FIG. 11 is a schematic diagram of the fourth embodiment of the present invention.

### DETAILED DESCRIPTION OF THE PREFERRED EMBODIMENTS

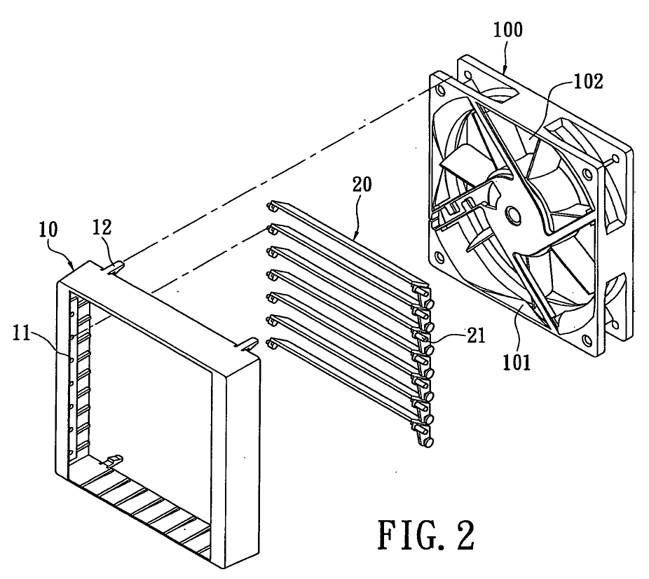

Reference is made to FIG. 2, which shows the first embodiment of the present invention. The fan airflow-guiding device matches a cooling fan 100. On the front side of the cooling fan 100, there is an outlet 101. On the rear side of the cooling fan 100, there is an inlet 102. The fan airflow-guiding device includes a frame 10, and a plurality of airflow-guiding boards 20.

The frame 10 is hollow. There is a plurality of pivoting holes 11 indented on the two inner side walls of the frame 10. The surrounding edge of the frame 10 extends backwards to form a plurality of wedged portions. In this embodiment, the wedged portion is a wedged hook 12.

The airflow-guiding boards 20 are disposed in parallel. The left side and the right side of each airflow-guiding board 20 respectively extend outwards to form a pivoting shaft 21. The pivoting shaft 21 corresponds to the pivoting hole 11 of the frame 10.

In this embodiment, the frame 10 is assembled on the cooling fan 100 by using the wedged portions (the wedged hooks 12). The frame 10 is installed on the front side of the cooling fan 100, but is not limited to this example.

The airflow-guiding boards 20 are disposed on the outlet 101 of the cooling fan 100 in a predetermined direction and in parallel. The pivoting shaft 21 of the airflow-guiding board 20 is correspondingly plugged into the pivoting hole 11 of the frame 10. Thereby, the airflow-guiding boards 20 are pivoted in the frame 10 at an inclined angle that is adjustable. The airflow-guiding boards 20 slant to the axial direction of the outlet 101 of the cooling fan 100, and guide the airflow exhausted from the cooling fan to a desired direction. The airflow direction is not restricted to the axial direction of the outlet 101.

The user can adjusting the slanting direction of the airflow-guiding boards 20 manually to guide the airflow exhausted from the cooling fan 100 to a predetermined direction for cooling a specified target object.

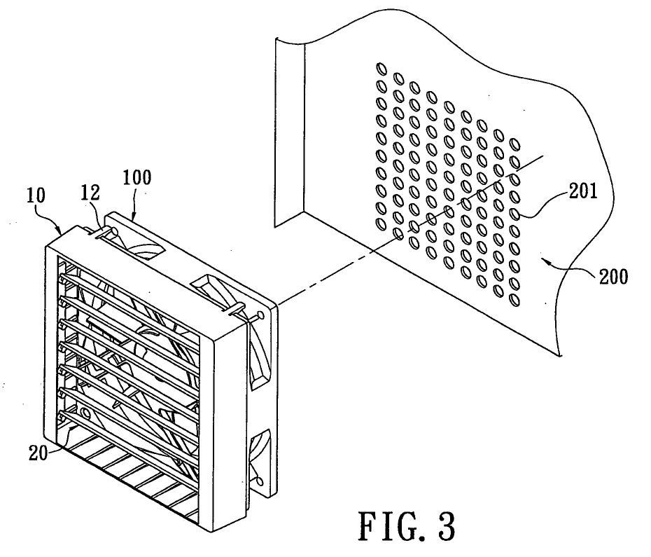

Reference is made to FIG. 3. When the fan airflow-guiding device is used, a housing is located on the rear side of the cooling fan 100. In this embodiment, the housing is a front board 200 of a computer host. The front board 200 has a plurality of cooling holes 201. The cooling holes 201 correspond to the inlet 102 located on the rear side of the cooling fan 100 (as shown in FIG. 2). The cooling fan 100 is installed on the front board 200 by a screwing, a wedged, or other fastening method.

The user can rotate the airflow-guiding boards 20 so that they become disposed at different slanted angles. For example, the upper half of the airflow-guiding boards 20 blow upwards, and the lower half of the airflow-guiding boards 20 blow downwards so that the airflow of the cooling fan 100 respectively blows to the power supply and the graphic card (not shown in the figure) in the computer host. Therefore, the cooling fan 100 absorbs cool air from outside of the housing (the front board 200) into the computer host via the cooling holes 201 to cool the heat source in the computer host.

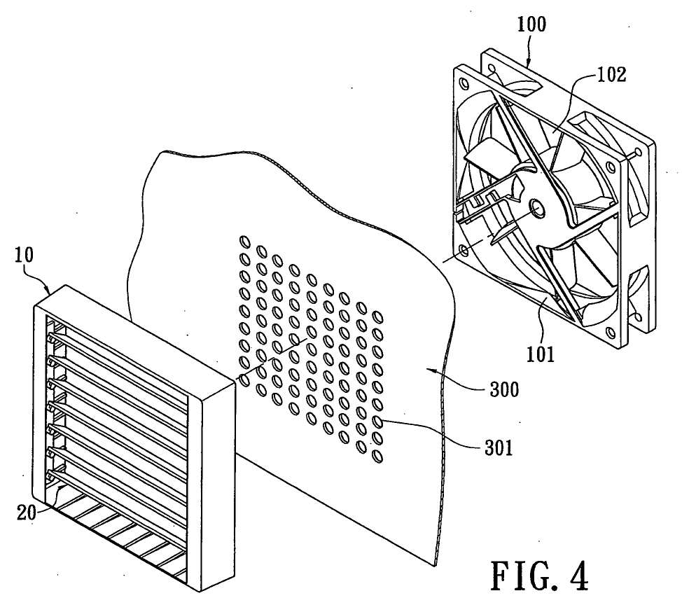

Reference is made to FIG. 4. There is a housing (in this embodiment, the housing is a side board 300 of a computer host) between the frame 10 and the cooling fan 100. The rear side of the frame 10 is located on the inner side surface of the side board 300. The outlet 101 located on the front side of the cooling fan 100 is located on the outer side surface of the side board 300. The side board 300 has a plurality of cooling holes 301 that correspond to the outlet 101 of the cooling fan 100. The frame 10 and the front side of the cooling fan 100 are respectively located on the two opposite sides of the side board 300 by a screwing, a wedging, or other fastening method. Thereby, the cooling fan 100 absorbs cool air from outside of the housing (the side board 300) into the computer host via the cooling holes 301 to cool the heat source in the computer host.

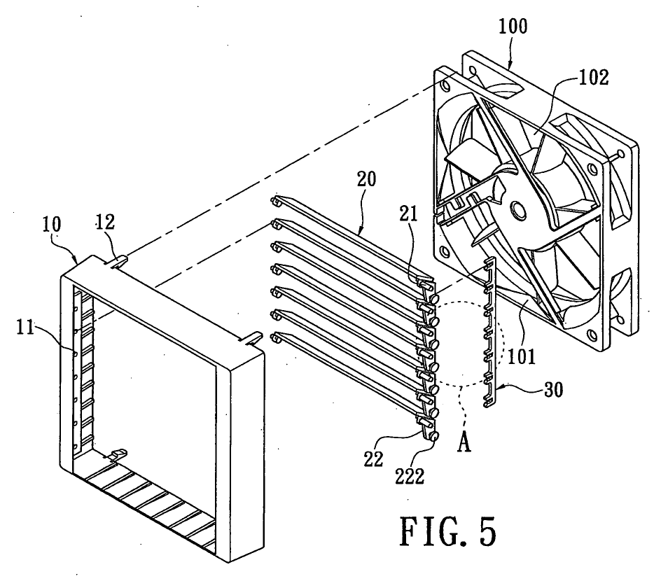

Reference is made to FIGS. 5˜7, which show the second embodiment of the present invention. The difference between the second embodiment and the first embodiment is:

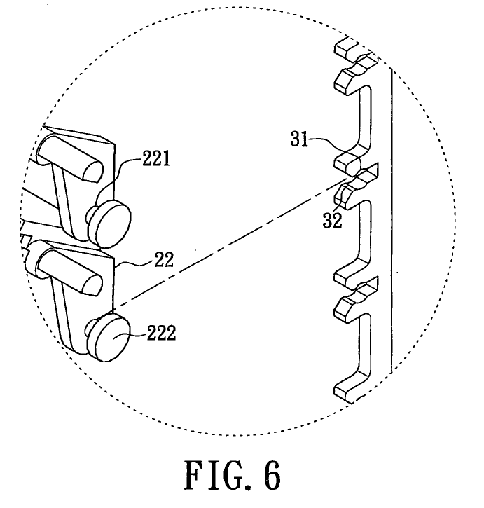

The right side of the airflow-guiding board 20 extends to form a side portion 22. The side portion that is close to the bottom protrudes to form a pivoting shaft 221 (as shown in FIG. 6). The pivoting shaft 221 is connected with a blocking portion 222 whose outer diameter is larger than the pivoting shaft 221.

The fan airflow-guiding device further has a linking rod 30 on the right side of the airflow-guiding boards 20. The linking rod 30 has a plurality of pivoting holes 31 disposed at the same distance that correspond to the pivoting shafts 221 (as shown in FIG. 6). Each pivoting hole 311inks with an opening slot 32. The opening slot 32 passes through the front side surface of the linking rod 30.

The pivoting shafts 221 of the side portions 22 pass through the opening slots 32 of the linking rod 30 and are pivoted in the pivoting holes 31 of the linking rod 30. The blocking portion 222 prevents the linking rod 30 from escaping from the side board 22. The side portions 22 are pivoted on the linking rod 30 at the same distance. Due to the linking rod 30, the airflow-guiding boards 20 synchronously rotate, and the slanting angle of the airflow-guiding boards 20 are the same as each other. Therefore, the airflow of the cooling fan is guided to a specified heat source (not shown in the figure) to cool the heat source more rapidly.

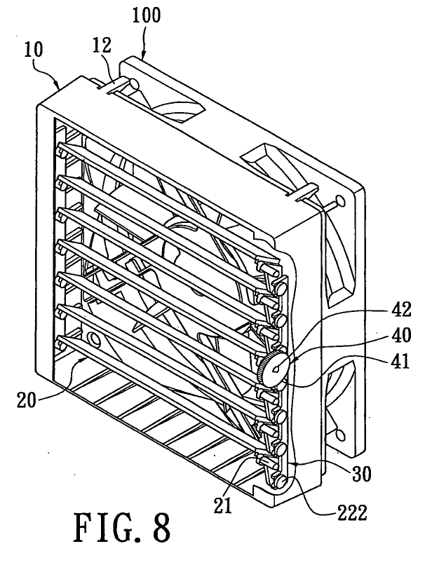

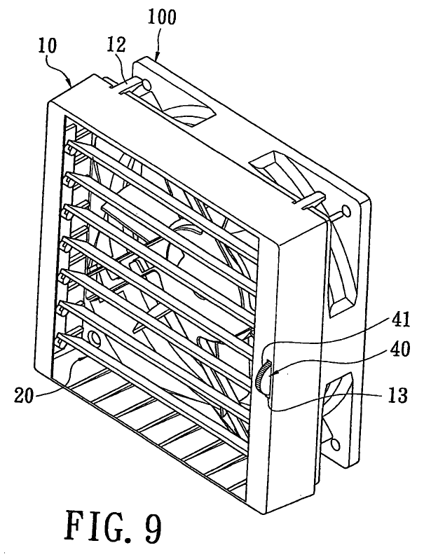

Reference is made to FIGS. 8 and 9, which shows the third embodiment of the present invention. The difference between the third embodiment and the second embodiment is:

The fan airflow-guiding device further has an adjusting structure. In this embodiment, the adjusting structure is a rotating wheel 40. The airflow-guiding boards 20 synchronously rotate due to the adjusting structure (the rotating wheel 40) matches the lining rod 30. On the surrounding edge of the rotating wheel 40, there is a sawtooth-shaped convex portion 41 that can be pushed by the user. At the center of the rotating wheel 40, there is a fastening hole 42 whose outline matches the pivoting shaft 21 of the airflow-guiding board 20 (in this embodiment, the cross-sectional surface of the pivoting shaft 21 and the fastening hole 42 are semi-circular. The rotating wheel 40 is located on a right side of one of the airflow-guiding boards 20 by matching the fastening hole 42 with the pivoting shaft 21 so that the rotating wheel 40 synchronously rotate with the airflow-guiding board 20.

On the surface of the frame 10, there is a through hole 13 that corresponds to the rotating wheel 40 (as shown in FIG. 9). The rotating wheel 40 passes through the through hole 13 and extends to an outside of the frame 10. It is convenient for the user to push.

When the user pushes the rotating wheel 40, the rotating wheel 40 makes the airflow-guiding board 20 rotate, and makes other airflow-guiding boards 20 synchronously rotate via the linking rod 30. Thereby, the slanting angles for all the airflow-guiding boards 20 are adjusted to the same one.

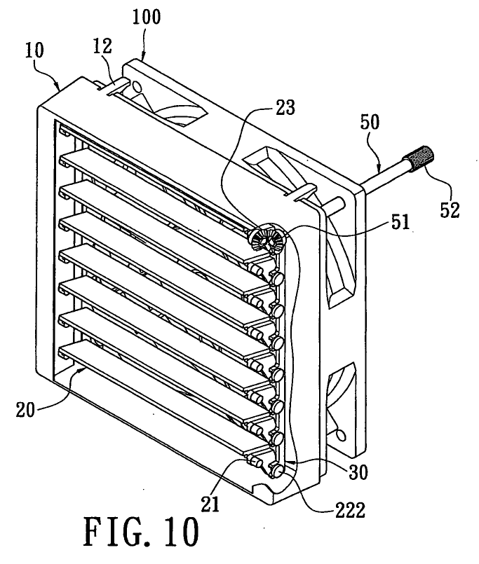

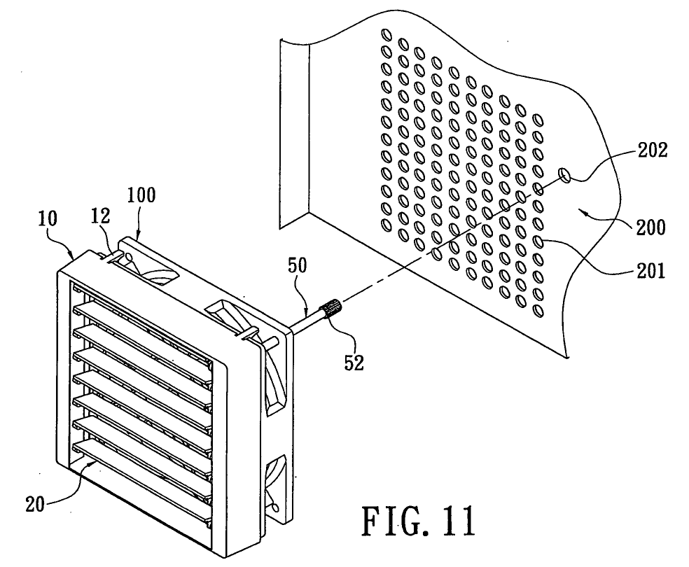

Reference is made to FIGS. 10 and 11, which show the fourth embodiment of the present invention. The difference between the fourth embodiment and the third embodiment is:

The adjusting structure includes an adjusting rod 50 that is located along the axial direction of the outlet 101 of the cooling fan 100, a first gear 51, and a second gear 23.

The first gear 51 is located on one end of the adjusting rod 50, and corresponds to the second gear 23. A second end of the adjusting rod 50 extends backwards to form a handle 52.

The second gear 23 is located on the right side of the airflow-guiding board 20 located at the upper-most location on the frame 10. The second gear 23 synchronously rotates with the airflow-guiding board 20. The second gear 23 gears with the first gear 51.

When the present invention is installed on the inner surface of the front board 200 of the computer host, the front board 200 has a through hole 202 that corresponds to the adjusting rod 50 (as shown in FIG. 11). The handle 52 of the adjusting rod 50 passes through the through hole 202 and extends to an outside of the front board 200 Therefore, the user can directly adjust the slanting angle of the airflow-guiding boards 20 from the outside of the front board 200.

The fan airflow-guiding device has a plurality of angle-adjustable airflow-guiding boards 20 on the outlet 101 of the cooling fan 100. The slanting angle of the airflow-guiding boards 20 can be changed according to the user's requirements. The airflow exhausted from the cooling fan 100 is guided to a specified location and the airflow direction is adjusted.

The present invention uses the cooling fan 100 to absorb cool air from the outside of the housing into the housing, and uses the airflow-guiding boards 20 to guide cool air to a target object that is to be cooled. Therefore, a heat source that is not located on the front side of the cooling fan 100 can be blown upon with cool air by the cooling fan. The cooing efficiency is thereby increased.

The present invention matches the cooling fan 100 to guide the airflow to a specified heat source, without changing the original structure of the cooling fan 100. The heat source has cool air blown upon it by the cooling fan 100 and is cooled more rapidly.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A fan airflow-guiding device, fitted with a cooling fan, one side of the cooling fan having an outlet, the fan airflow-guiding device comprising:
a frame assembled on one side of the cooling fan; and
a plurality of airflow-guiding boards pivoted in the frame, wherein the airflow-guiding boards are disposed on the outlet of the cooling fan in a predetermined direction and in parallel.

2. The fan airflow-guiding device as claimed in claim 1, wherein the airflow-guiding boards slant to an axial direction of the outlet.

3. The fan airflow-guiding device as claimed in claim 2, wherein slanting angles for all the airflow-guiding boards are the same as each other.

4. The fan airflow-guiding device as claimed in claim 2, wherein slanting angles of part of the airflow-guiding boards are different from slanting angles of other airflow-guiding boards.

5. The fan airflow-guiding device as claimed in claim 1, wherein one side of each airflow-guiding board extends to from a side portion, and the side portions are pivoted on a linking rod at the same distance.

6. The fan airflow-guiding device as claimed in claim 5, further comprising an adjusting structure, wherein the airflow-guiding boards synchronously rotate by fitting the adjusting structure with the linking rod.

7. The fan airflow-guiding device as claimed in claim 6, wherein the adjusting structure is a rotating wheel, the rotating wheel is located on one side of one of the airflow-guiding boards and synchronously rotates with the airflow-guiding board.

8. The fan airflow-guiding device as claimed in claim 6, wherein the adjusting structure includes an adjusting rod, a first gear, and a second gear, the first gear being located on one end of the adjusting rod, the second gear being located on one side of one of the airflow-guiding boards and rotating synchronously with the airflow-guiding board, and the first gear gears with the second gear.

9. The fan airflow-guiding device as claimed in claim 1, wherein a second side of the cooling fan has a housing and an inlet, and the housing has a plurality of cooling holes that correspond to the inlet.

10. The fan airflow-guiding device as claimed in claim 1, wherein there is a housing between the frame and the cooling fan, the frame and one side of the cooling fan are respectively located on two opposite sides of the housing, and the housing has a plurality of cooling holes that correspond to the outlet of the cooling fan.
